(19) United States
(12) Patent Application Publication
(10) Pub. No.: US 2020/0071160 A1
(43) Pub. Date: Mar. 5, 2020

(54) METHOD FOR FORMING MICROSTRUCTURES

(71) Applicant: EPIGEM LIMITED, Redcar Cleveland (GB)

(72) Inventors: Richard TRAYNOR, Redcar Cleveland (GB); Tim, George RYAN, Redcar Cleveland (GB)

(21) Appl. No.: 16/468,095

(22) PCT Filed: Dec. 11, 2017
(86) PCT No.: PCT/GB2017/053704

§ 371 Date: Jun. 10, 2019

(30) Foreign Application Priority Data
Dec. 9, 2016 (GB) 1620953.8

(51) Int. Cl. B81C 1/00; B01D 67/00; B01D 69/00; B01D 71/00; B32B 15/04; B32B 15/18; B32B 15/20; B32B 3/08; B32B 3/26; B32B 3/30; C25D 1/08; C25D 1/20; C25D 3/12

(52) U.S. Cl. CPC B81C 1/00103; B32B 2307/206; B01D 69/00; B01D 71/00; B32B 15/04; B32B 15/18; B32B 15/20; B32B 3/08; B32B 3/263; B32B 3/30; C25D 1/08; C25D 1/20; C25D 3/12; B81C 1/00063; B32B 2307/202; B01D 67/00

(57) ABSTRACT

A method for producing a microstructure is disclosed. A master is provided having a pattern formed of conductive material embedded in a non-conducting substrate. The master has a master surface having a conducting portion defined by the pattern and a non-conducting portion defined by the non-conducting substrate. A surface treatment is applied to the master surface to alter the adhesion properties of at least one of the conducting portion or the non-conducting portion. The microstructure is formed by deposition or plating of a functionalising material onto the master surface, and the microstructure is then separated from the master. The master can be reused.

### FIELD OF THE INVENTION

The invention relates to microstructures and to methods of forming microstructures. The invention has particular use in forming microstructure meshes having line width less than 10 μm, though the invention is applicable to other microstructures.

### BACKGROUND AND PRIOR ART

Microstructures are small scale structures having features in the region of 1-100 μm. A common microstructure is a mesh, though other microstructures are also possible. Two applications where microstructure meshes have proved useful are touch screen displays and EMI shielding of plasma displays. To be suitable for these applications, a microstructure mesh with line widths of less than 10 μm is required so that the mesh is barely noticeable to a viewer of the display. The mesh is formed of a conductive material such as copper or nickel. For ease of handling, the mesh is usually provided on a transparent film.

Microstructure meshes are also used for filtering, such as in microfluidic filters. These meshes are not provided on a film, which would interfere with the filtering action.

US patent specification 2003/0136572 describes one method of manufacturing a metal mesh whereby sheets of copper are coated with a photoresist which is then exposed and developed. Exposed copper not covered by developed photoresist is etched away and the photoresist removed. In this way a copper mesh with 10 μm line width and 300 μm pitch can be made.

Another manufacturing method involves masking a first PET film with photoresist to leave exposed the desired shape of the mesh. The masked first film is used to emboss a curable resin in the desired shape of the mesh onto a second PET film by providing the curable resin between the masked film and the second film, then applying pressure using a roller. After curing the resin, the second film and cured resin are peeled away from the first film. This second film is used to emboss a curable resin onto a conductive substrate in a similar manner. A suitable conductive material, such as nickel or gold, is then formed onto the exposed conductive substrate by electroplating or other electro-deposition process. A transparent film is laminated onto the resin and conductive material using an adhesive. The transparent film is then removed from the conductive substrate along with the resin and conductive material due to the adhesive. The conductive material forms the microstructure mesh, which is embedded in the resin, on the transparent film. A conductive substrate with low surface roughness is preferred to ensure the conductive material does not tear or remain bonded to the conductive substrate. Examples of low surface roughness conductive substrates include sputtered nichrome/copper on PEN film and low roughness electrodeposited nickel foil on PET film, both of which have surface roughness less than 20 nm.

The manufacturing cost of microstructures remains a challenge. In the first method described above, over 90% of the copper sheet is etched away and wasted. In the second method described above, the need for low surface roughness on the conductive substrate together with a limited number of re-uses before the conductive surface degrades adds cost to the process.

The invention has been made in view of the above-mentioned challenges. An object of the invention is to provide a method for producing microstructures which provides a lower cost alternative to the methods described above.

### SUMMARY OF THE INVENTION

The term ‘pattern’ is used in this specification to mean both repeating and non-repeating patterns.

In accordance with a first aspect of the invention, there is provided a method for producing a microstructure, comprising:
Providing a master having a pattern formed of conductive material embedded in a non-conducting substrate, the master including a master surface having a conducting portion defined by the pattern and a non-conducting portion defined by the non-conducting substrate;
Applying a surface treatment to the master surface to alter the adhesion properties of at least one of the conducting portion or the non-conducting portion thereof;
Forming the microstructure by deposition or plating of a functionalising material onto the master surface; and
Separating the microstructure from the master.

In one embodiment, the method further comprises the step of depositing or plating a first layer of conductive material onto the conducting portion of the master surface prior to the step of applying a surface treatment to the master surface.

Preferably, wherein the first layer has a thickness between 0.25-1.51 μm.

Preferably, the method further comprises the steps of depositing or plating a second layer of conductive material onto first layer after the step of applying the surface treatment, and removing the first and second layers of conductive material prior to forming the microstructure.

In one embodiment, the step of applying a surface treatment comprises immersing the master in a dilute solution of an oxidising agent for a predetermined time to at least partially passivate the conducting portion. One example of a suitable oxidising agent is potassium dichromate.

In another embodiment, the step of applying a surface treatment comprises treating the master surface with a solution to reduce the surface energy of the master surface.

Preferably, the method further comprises the step of applying a stencil onto the master surface prior to the step of forming the microstructure.

Preferably, the step of forming the microstructure comprises deposition or plating of a functionalising material having a thickness less than 101 μm.

Preferably, the step of forming the microstructure comprises deposition or plating of a plurality of layers in turn, each layer formed of a functionalising material.

In one embodiment, wherein the pattern comprises an auxetic pattern.

Preferably, the or each functionalising material is suitably selected from the group consisting of metals from Groups Va, Via, Vila, VIII, Ib, IIb, IIIb, IVb, Vb, VIb, and the actinides of the Periodic Table of the Elements, for example, V, Cr, Mo, W, Mn, Re, Fe, Co, Rh, Ni, Pd, Pt, Cu, Ag, Au, Zn, Cd, Al, C, Si, Sn, Pb, Sb, P, Te, Th, and alloys thereof; and from known UV curable magneto, ferro or electrically active polymer, for example selected from but not limited to processable forms of polyaniline, polyvinylene, polythiophene, polypyrrole, polyphenylene, polyphenylenevinylene and precursors, analogues or copolymers thereof.

Preferably, the method further comprises applying at least one coating to the mesh, the or each coating selected from the list comprising: phenolic compounds, catechol, gallates, catechin compounds, mussel adhesive protein, antigens including peptide epitopes, aptamers and antibodies, polymer syntheses using DOPA and dopamine derivatives, monomers, copolymers formed from acetonide-protected dopamine methacrylamide (ADMA) and at least one of methyl methacrylate, hydroxyl ethyl methacrylate, poly(ethylene glycol) methacrylates, longer alkyl methacrylates such as stearyl methacrylate or glycidyl methacrylate. Other suitable monomers may also be used with ADMA, such as acrylates.

Preferably, the step of separating the microstructure comprises peeling the microstructure from the master.

Preferably, the method further comprises the step of laminating a film to the microstructure prior to separating the microstructure from the master.

Preferably, the steps of applying a surface treatment, forming, and separating, are repeated using the same master.

Preferably, the pattern has a feature width less than a desired feature width of the microstructure. More preferably, the pattern has a feature width less than 75% of the desired feature width of the microstructure. Still more preferably, the pattern has a feature width less than 50% of the desired feature width of the microstructure.

Preferably, the step of providing a master comprises:
Providing a conductive substrate;
Forming onto a conducting substrate, the non-conducting substrate patterned to leave trenches where the conducting substrate is exposed;
Applying a surface treatment to the exposed conductive substrate to reduce the adhesion properties thereof;
Forming a pattern of conductive material by depositing or plating the conductive material onto the exposed conductive substrate;
Laminating a film to the non-conducting substrate and pattern using an adhesive; and
Separating the film, conductive material and non-conductive substrate from the conductive substrate to form the master.

Preferably, the method further comprises the step of forming several masters from each conductive substrate.

In accordance with a second aspect of the invention there is provided a microstructure produced by the method of the first aspect.

### BRIEF DESCRIPTION OF THE FIGURES

Embodiments of the invention will now be described, by way of example, with reference to the accompanying drawings in which:

FIG. 1 is a cross-section view of a master for forming a microstructure in the form of a mesh;

FIG. 2 is a top-down view of the master shown in FIG. 1;

FIG. 3 is a cross section view of the master of FIG. 1 with a thin layer of conductive material deposited thereon;

FIG. 4 is a cross section view of the master of FIG. 1 with a microstructure mesh formed thereon;

FIG. 5 is a top-down view of the master shown in FIG. 4 with the microstructure mesh formed thereon;

FIG. 6 is a side view showing separation of the microstructure mesh from the master of FIG. 1;

FIG. 7 is a side view showing lamination of the microstructure mesh to a transparent film;

FIGS. 8 and 9 are examples of microstructures formed according to the invention.

### DESCRIPTION OF PREFERRED EMBODIMENTS

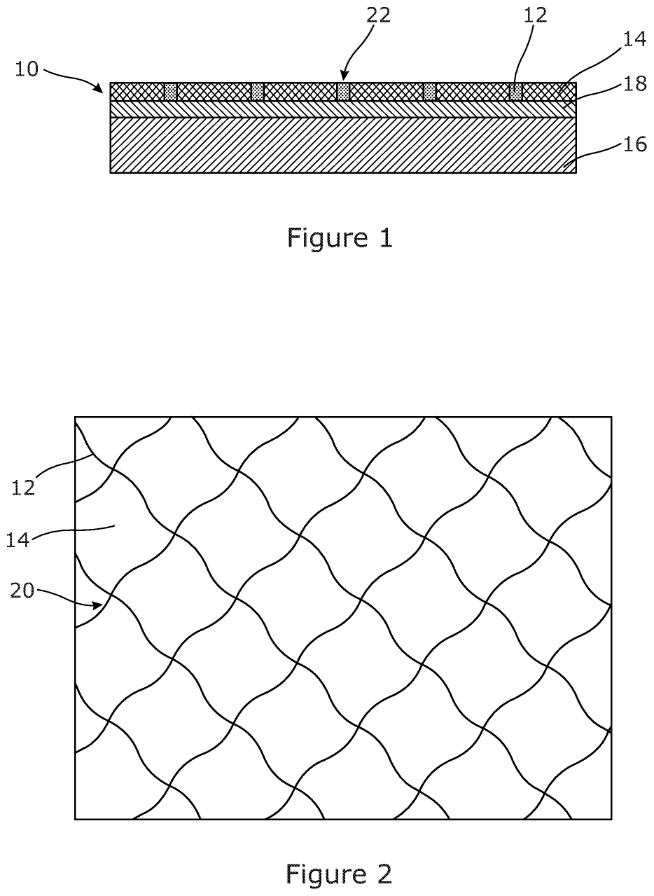

The first embodiment relates to the production of a microstructure from a master. FIG. 1 shows a master 10 having a pattern of conductive material 12, such as nickel, embedded in a non-conductive substrate 14. The conductive material 12 and non-conductive substrate 14 are provided on a PET film 16 using an adhesive layer 18. The PET film 16 improves handleability of the master 10 and may extend the working life of the master 10. The master 10 has a surface 22 having a conducting portion defined by the pattern 12 and a non-conducting portion defined by the non-conducting substrate 14.

FIG. 2 shows a top view of the master 10 in which it can be seen the pattern of conductive material 12 forms a mesh 20 embedded in the non-conductive substrate 14. Thus, the master 10 of the embodiment is configured to produce a microstructure in the form of a mesh; the term microstructure mesh is used in this embodiment to refer to the microstructure, however it will be appreciated that the invention is applicable to other forms of microstructure.

The non-conducting substrate 14 may be formed of any suitable resin, such as CER003 resin composed of 45.8% Ebecryl IBOA available from Allnex, 30.4% CN104D80 available from Arkema, 20% Ebecryl 639 available from Allnex, 2% Genocure BDK available from Rahn and 1.9% Darocur 1173 available from BASF.

Prior to forming a microstructure mesh, a surface treatment is applied to the surface 22 of the master 10 as follows. The master is first placed in a dilute solution of an oxidising agent, such as potassium dichromate, in deionised water to reduce the adhesion properties of the conductive portion of the surface 22. It has been found that 1-2% w/w solution of potassium dichromate for 2 minutes is adequate, however other combinations of dilution and time are also possible. The reduction in adhesion properties prevents the microstructure that is subsequently formed (as described below) from strongly bonding to the conductive material 12 so as to inhibit its removal. It has been found that without surface treatment there is a tendency for the formed microstructure to be difficult to remove from the master and/or to tear during removal. The surface treatment must not be so thorough as to prevent the microstructure from being formed, however.

The purpose of the surface treatment is to prevent strong adhesion between the functionalising material from which the microstructure is formed and the conductive material 12 to permit the microstructure to be removed from the master later on. However, sufficient adhesion must remain to prevent premature separation of the microstructure from the conducting materials during the plating process. Other means of obtaining precise control of adhesion properties, that are pattern or materials combination dependent, are described below.

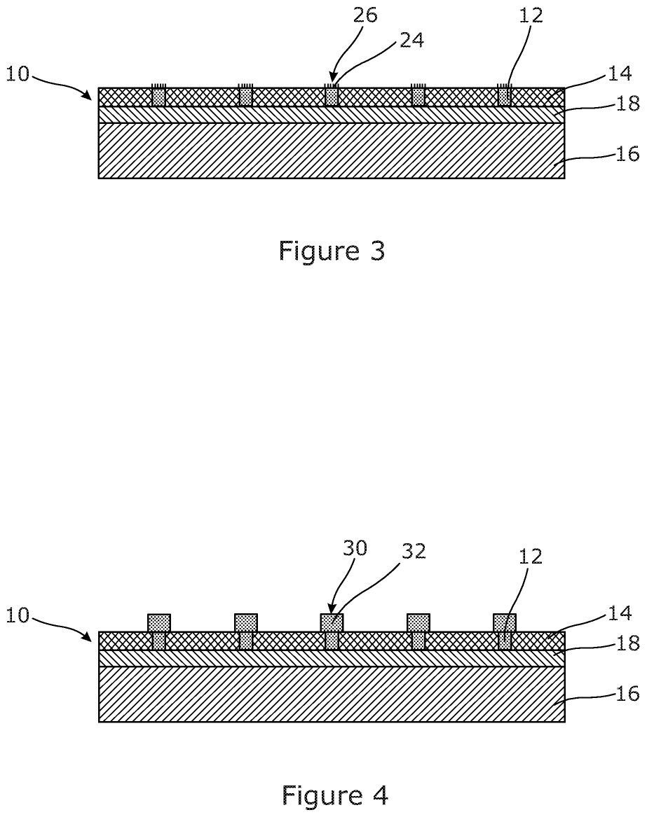

While surface treatment is necessary to facilitate removal of the formed microstructure from the master 10 it is also necessary that the master 10 is able to be handled after the microstructure is formed. It has been discovered that if the surface 22 of the conductive material 12 is too smooth then the formed microstructure may not adhere to the conductive material 12 sufficiently to permit handling. This is particularly the case when large features are included in the microstructure and where the roughness of the surface 22 is less than 20 nm, as would be the case when the master 10 is formed according to the background art described above.

Where the surface 22's roughness is so low that its adhesion properties may already result in the difficulties described above, a first layer 24 of nickel or other suitable conductive material may be plated or deposited onto the conductive portion of surface 22 prior to the step of applying a surface treatment, as shown in FIG. 3. The first layer 24 presents a rougher surface 26 to which the formed microstructure can adhere sufficiently to permit handling of the master 10. In the embodiment the first layer 24 is formed by immersing the master in the nickel PC-8 bath described below for 10 min with a 2 amp plating current. While the remainder of the description will refer to a master which has not had a first layer 24 formed thereon it will be understood that the remaining process steps would apply equally to a master with a first layer 24, and that references to the surface 22 below apply equally to the surface 26 when a first layer 24 is formed on the master 10.

After applying the surface treatment as described above, a microstructure mesh 30 is formed by deposition or plating of a functionalising material 32 onto the conductive portion of surface 22, as shown in FIG. 4.

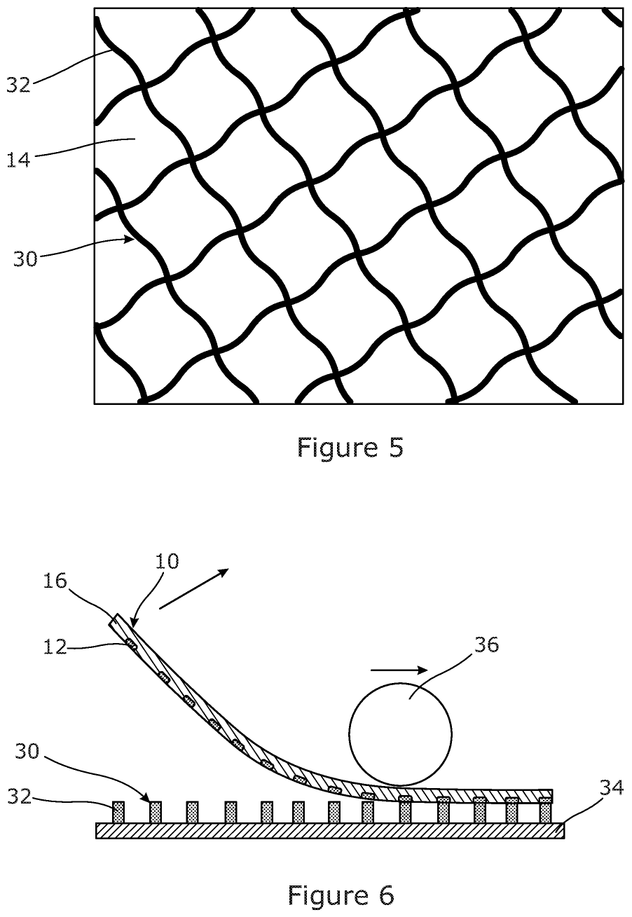

In one embodiment the microstructure mesh 30 is formed using nickel as the functionalising material and which is applied by nickel plating. The master 10 is placed in a plating bath made up at 340 g/l nickel sulphamate, 11.7 g/l NiCL₂, 40 g/l boric acid, and 2.5 g/l additive. The bath is operating at pH4, at 45° C. An electrode is attached to the master 10 using a clamp which forms a conducting contact with the conductive material 12. The master 10 is then plated to form the microstructure mesh 30. It has been found that plating for 4 mins at 4-6 amps provides good results for the mesh shown in FIG. 5. It has been found that the plating conditions may need to be varied to suit the pattern on the master 10.

After plating, the master 10 is rinsed for 3 min in 40° C. water followed by rinsing for 2 min in room temperature deionised water. The master 10 is then blown dry with compressed air. The master 10 may be alternatively placed in an oven at 80° C. to dry.

As shown in FIG. 4 the microstructure mesh 30 is broader than the mesh 20 embedded in the non-conductive substrate 14. This broadening is a result of the electroplating process being used in the absence of masking or other relief forming process to constrain lateral growth. The resulting microstructure mesh 30 is shown in FIG. 5, which can be contrasted with FIG. 2 to see the track broadening of the microstructure mesh 30 compared to the mesh 20. The mesh 30 is illustrated as being rectangular in cross-section in the drawings, however as will be apparent to the skilled person, the mesh 30 may have other profiles in cross-section depending on the functionalising material(s) used and plating/deposition settings employed.

The broadening of the microstructure mesh 30 can be partially compensated for by providing a master 10 with a pattern of conductive material 12 having a feature width narrower than a desired feature width of the microstructure 30. Depending on the application and desired thickness of the microstructure, the pattern may have a feature width, such as a line width, less than 50-75% of the desired feature width of the microstructure.

Functionalising materials other than nickel may be used according to the required characteristics of the microstructure mesh 30. For example, functionalising materials may be suitably selected from the group consisting of metals from Groups Va, Via, Vila, VIII, Ib, IIb, IIIb, IVb, Vb, VIb, and the actinides of the Periodic Table of the Elements, for example, V, Cr, Mo, W, Mn, Re, Fe, Co, Rh, Ni, Pd, Pt, Cu, Ag, Au, Zn, Cd, Al, C, Si, Sn, Pb, Sb, P, Te, Th, and alloys thereof; and from known UV curable magneto, ferro or electrically active polymer, for example selected from but not limited to processable forms of polyaniline, polyvinylene, polythiophene, polypyrrole, polyphenylene, polyphenylenevinylene and precursors, analogues or copolymers thereof.

Further, in other embodiments the microstructure mesh 30 may be formed of two or more layers of different functionalising materials. In addition, one or more coatings may applied to the mesh 30 once formed, examples of which include: phenolic compounds, catechol, gallates, catechin compounds, mussel adhesive protein, antigens including peptide epitopes, aptamers and antibodies, polymer syntheses using DOPA and dopamine derivatives, monomers, copolymers formed from acetonide-protected dopamine methacrylamide (ADMA) and one of methyl methacrylate, hydroxyl ethyl methacrylate, stearyl methacrylate or glycidyl methacrylate. An outer layer of suitable functionalising material may be formed on the mesh 30 prior to application of a coating, for instance an outer layer of gold (Au) may be applied.

Next, the microstructure mesh 30 is separated from the master 10. One way of achieving this is shown in FIG. 6, where the master 10 was placed face down on a carrier, such as cleanroom paper 34, so that the microstructure mesh 30 is touching the paper 34. One edge of the master 10 is lifted and peeled away from the microstructure mesh 30. Once the peeling has started, the peeling is then completed using a roller 36 pressing on the master 10. The master 10 is lifted as the roller 36 advances across it to remove the microstructure mesh 30 from the master 10. Pressure from the roller 36 prevents the master 10 from pulling away from the paper 34 as it is lifted, resulting in the force from lifting the master 10 being applied to separate the microstructure mesh 30 from the surface 22 of the conductive material 12. The microstructure mesh 30 remains on the paper 34 as the master 10 is lifted. The microstructure mesh 30 may then be separated from the paper 34 in a similar manner, by peeling the paper 34 from the mesh 30 to leave the mesh self-supporting. Alternatively the paper 34 or other carrier could be removed in any other suitable manner apparent to the skilled person, such as dissolving the paper. Further, other methods of removing the mesh may be adopted.

Surface treatment of the surface 22 aids in separation of the microstructure mesh 30 from the surface 22, as described above, and also preserves the surface 22 so that the master 10 may be reused. Those skilled in the art may refer to the surface treatment of the surface 22 as partial passivation. Other methods of removing the microstructure mesh 30 from the surface 22 may be used. Where the microstructure is made in a reel to reel process, the microstructure may be removed by contacting it with a film having sufficient adhesion to overcome the adhesion of the microstructure to the partially passivated surface 22. In some arrangements the microstructure may be retained on the film, or it may be removed from it according to the application.

Multiple microstructure meshes 30 can be produced from a single master 10 by repeating the process from the step of partial passivation. Reuse of the master lowers the cost of producing microstructures.

The second embodiment relates to the production of a microstructure mesh from a master in which the microstructure is provided on a transparent film. Like reference numerals are used to denote like parts to those of the first embodiment.

The production of the microstructure mesh 30 of the second embodiment uses a similar process to that of the first embodiment. The steps of partial passivation of the embedded mesh 20 in the master 10 and forming the microstructure mesh 30 by plating or depositing a functionalising material 32 are performed in the same manner as the first embodiment.

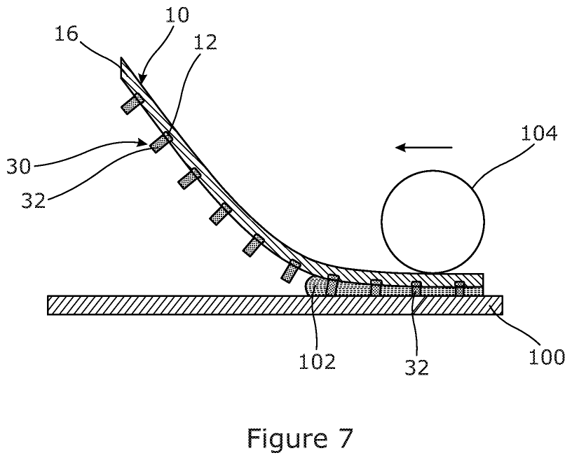

Next, the microstructure mesh 30 is laminated to a film 100. Depending on the intended application, the film 100 may be transparent. One way to achieve this is shown in FIG. 7, in which the film 100, formed of polyethylene terephthalate (PET) in the embodiment one suitable example of which is ST505 polyester film from Dupont Teijin Films, is placed on a flat surface. The master 10 is placed on top of the film 100 with the microstructure mesh 30 facing towards the film 100. A curable adhesive 102, such as Norland 64 adhesive available from Norland, is introduced between the master 10 and film 100. A roller 104 is used to apply pressure and laminate the master 10 and film 100 together. Placing the master 10 above the film 100 prevents air bubbles being trapped in the adhesive during lamination.

The laminated master 10 and film 100 is then inverted and the adhesive 102 cured. The master 10 is then lifted and peeled away the same manner as described above in relation to the first embodiment, leaving the microstructure mesh 30 embedded in the adhesive 102 on the film 100.

Alternatively, rather than using a curable adhesive, a layered polymeric film such as co-extruded polyethylene/PET film can be used to laminate to the microstructure. The microstructure may then be pressed into the film. If necessary, heat may be applied to soften the embedding layer and aid the process. In the case of co-extruded polyethylene/PET film is has been found that lamination at temperatures of 90-110° C. provides good results. At this temperature the microstructure becomes embedded within the film. A further alternative is to use a film with an adhesive layer preformed thereon, in which case the microstructure may be transferred to the film by lamination.

The master 10 can then again be reused, by repeating the steps from partial passivation onwards, to produce multiple microstructure meshes.

In some instances it may be necessary to apply a surface treatment to the non-conductive substrate 14 to reduce its adhesive properties and prevent the adhesive or film from adhering to the master 10. One suitable treatment is to immerse the master in a solution made up as follows: 1% fluorolink S10, 4% water, 1% acetic acid, 94% isopropyl alcohol, and referred to herein as the ‘S10 solution’. Again, the treatment time may vary according to the adhesive or film used, however it has been found that immersion for around 10 minutes yields good results. Other solutions known to those skilled in the art to reduce surface energy may also be suitable according to the material from which the non-conductive substrate is formed.

After immersion, the master 10 is rinsed twice in 95/5% w/w isopropyl alcohol/water solution before being baked for 30 minutes at 100° C. The master was then baked for a further 15 minutes at 150° C. The baking removes any water and isopropyl alcohol from the master 10.

Immersion in the S10 solution results in treatment of all exposed surfaces, including the conductive and non-conductive portions of the surface 22. Since only treatment of the non-conductive portion of the surface, namely the non-conductive substrate 14, is desired, a first layer of conductive material such as nickel may be deposited onto the pattern in the master 10 prior to immersion in the S10 solution using the method described above. Once the master 10 has been baked, a second layer conductive material is deposited using the method above and without any further surface treatment. This results in a thickening of the deposited conductive material and adhesion of the first layer to the second layer. The first and second layers of conductive material are then peeled away and discarded leaving the S10 treatment everywhere on the surface 22 of the master 10 apart from the conductive portions. The microstructure can then be formed on the master 10 as described above. The microstructure can be laminated to any adhesive or film, and the adhesive will stick to the microstructure however the S10 surface treatment prevents adhesion to the other areas of the surface 22. It is not necessary to re-treat the master 10 using S10 solution for every microstructure formed on the master 10.

One method for producing a master will now be described, by way of example. First, a non-conductive substrate such as SU-8 photoresist is masked using standard photo-lithography onto a low surface roughness nickel foil provided on a PET film. The nickel foil forms a conductive substrate. The SU-8 photoresist is masked to form a pattern which leaves trenches where the nickel foil is exposed. The master may then be plasma ashed for 1-2 minutes to remove any traces of photoresist from the exposed portions of the nickel foil and to improve wetting during plating.

The exposed portions of the nickel foil are then passivated for 2 mins in a 1-2% w/w solution of potassium dichromate in deionised water.

Next, a suitable conductive material, preferably nickel, is electroplated onto the exposed portions of the nickel foil using the PC-8 bath described above for 10 mins at 8 amps to form a pattern of conductive material embedded in the SU-8 substrate. After plating, the substrates are then rinsed for 3 mins in 40° C. water followed by 2 mins in room temperature deionised water before being blown dry with compressed air.

The SU-8 photoresist and nickel mesh are laminated to a PET film using a thin layer of an adhesive Estasol 2107 isocyanate cross-linking adhesive (ICPA). The laminate was allowed to cure for 12 hours at room temperature since accelerated curing at elevated temperatures would affect the adhesion of the SU-8 photoresist to the conductive nickel substrate and affect separation of the photoresist from the conductive nickel substrate.

The film was then peeled away from the conductive substrate, with the adhesive layer, SU-8 photoresist and mesh peeling away with the film to form the master. Advantageously, the conductive substrate may be re-used to make other masters. Thus, one conductive substrate may be used to make a plurality of masters, each of which can be used to make a plurality of microstructures. This provides for lower costs of manufacture compared to either directly etching the pattern onto the conductive substrate or producing the microstructure directly from the conductive substrate, since films having low surface roughness metal foils are costly.

In some instances, it may be desired to produce a plurality of microstructures from a single master. These microstructures may be continuous or discrete. Producing the plurality of microstructures may be achieved by providing a stencil onto the master prior to forming the microstructures, to confine where on the master the microstructures will be formed. Such a stencil may be a removable film.

Alternatively, producing the plurality of microstructures may be achieved by forming a master with discrete patterns therein in order to confine where microstructures are formed. In this case a conductive backing is needed on the master to provide conduction for electrodeposition or electroplating. The conductive backing could be formed by sputtering, for instance. Other ways of providing a conductive backing may also be used.

In some embodiments, the master may be provided on a supporting film to increase durability and handleability of the master.

A wide variety of microstructures may be formed using the method described above. One example of a microstructure is shown in FIG. 5: a wavy mesh. Other microstructure meshes could also be formed: straight mesh, as well as mesh formed from tessellating shapes other than squares, whether with straight or wavy segments. Meshes with line widths from 5 μm to 50 μm and pitches of 50 to 300 μm have been produced using the process detailed above. Such meshes have been transferred onto PE/PET film or released from the master as free standing mesh.

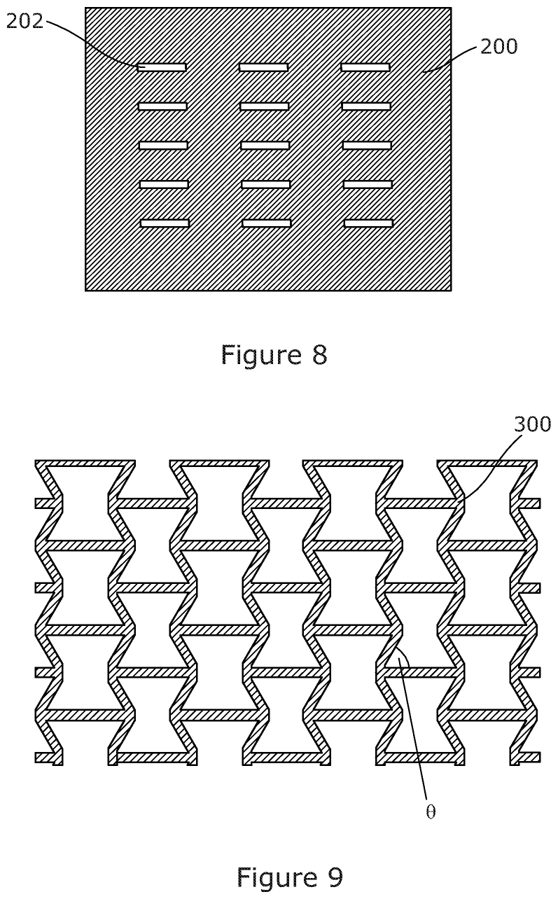

Microstructures are not confined to meshes, however. FIG. 8 shows a microstructure comprising a sheet 200 with slots 202 formed therein. The slots 202 have slot widths ranging from 2-10 μm and lengths ranging from 20-100 μm.

FIG. 9 shows yet another example of a microstructure formed using the above method. The microstructure shown in FIG. 9 has a generally auxetic structure 300; other auxetic and conformable structures are also possible. For instance, microstructures where the varying angle θ in FIG. 9 is in the range of 45°-60° have been made.

1. A method for producing a microstructure comprising:
Providing a master having a pattern formed of conductive material embedded in a non-conducting substrate, the master including a master surface having a conducting portion defined by the pattern and a non-conducting portion defined by the non-conducting substrate;
Applying a surface treatment to the master surface to alter the adhesion properties of at least one of the conducting portion or the non-conducting portion thereof;
Forming the microstructure by deposition or plating of a functionalising material onto the master surface; and
Separating the microstructure from the master.

2. The method of claim 1, further comprising the step of depositing or plating a first layer of conductive material onto the conducting portion of the master surface prior to the step of applying a surface treatment to the master surface.

3. The method of claim 2, wherein the first layer has a thickness between 0.25-1.5 μm.

4. The method of claim 2, further comprising the steps of depositing or plating a second layer of conductive material onto first layer after the step of applying the surface treatment, and removing the first and second layers of conductive material prior to forming the microstructure.

5. The method of claim 1, wherein the step of applying a surface treatment comprises immersing the master in a dilute solution of an oxidising agent for a predetermined time to at least partially passivate the conducting portion.

6. The method of claim 1, wherein the step of applying a surface treatment comprises treating the master surface with a solution to reduce the surface energy of the master surface.

7. The method of claim 1, further comprising the step of applying a stencil onto the master surface prior to the step of forming the microstructure.

8. The method of claim 1, wherein the step of forming the microstructure comprises deposition or plating of a functionalising material having a thickness less than 10 μm.

9. The method of claim 1, wherein the step of forming the microstructure comprises deposition or plating of a plurality of layers in turn, each layer formed of a functionalising material.

10. The method of claim 1, wherein the pattern comprises an auxetic pattern.

11. The method of claim 1, wherein the or each functionalising material is suitably selected from the group consisting of metals from Groups Va, VIa, VIIa, VIII, Ib, IIb, IIIb, IVb, Vb, VIb, and the actinides of the Periodic Table of the Elements, for example, V, Cr, Mo, W, Mn, Re, Fe, Co, Rh, Ni, Pd, Pt, Cu, Ag, Au, Zn, Cd, Al, C, Si, Sn, Pb, Sb, P, Te, Th, and alloys thereof; and from known UV curable magneto, ferro or electrically active polymer, for example selected from but not limited to processable forms of polyaniline, polyvinylene, polythiophene, polypyrrole, polyphenylene, polyphenylenevinylene and precursors, analogues or copolymers thereof.

12. The method of claim 1, further comprising applying at least one coating to the mesh, the or each coating selected from the list comprising: phenolic compounds, catechol, gallates, catechin compounds, mussel adhesive protein, antigens including peptide epitopes, aptamers and antibodies, polymer syntheses using DOPA and dopamine derivatives, monomers, copolymers formed from acetonide-protected dopamine methacrylamide (ADMA) and at least one of methyl methacrylate, hydroxyl ethyl methacrylate, poly(ethylene glycol) methacrylates, longer alkyl methacrylates such as stearyl methacrylate or glycidyl methacrylate.

13. The method of claim 1, wherein the step of separating the microstructure comprises peeling the microstructure from the master.

14. The method of claim 1, further comprising the step of laminating a film to the microstructure prior to separating the microstructure from the master.

15. The method of claim 1, wherein the steps of applying a surface treatment, forming, and separating, are repeated using the same master.

16. The method of claim 1, wherein the pattern has a feature width less than a desired feature width of the microstructure.

17. The method of claim 16, wherein the pattern has a feature width less than 75% of the desired feature width of the microstructure.

18. The method of claim 17, wherein the pattern has a feature width less than 50% of the desired feature width of the microstructure.

19. The method of claim 1, wherein the step of providing a master comprises:
Providing a conductive substrate;
Forming onto a conducting substrate, the non-conducting substrate patterned to leave trenches where the conducting substrate is exposed;
Applying a surface treatment to the exposed conductive substrate to reduce the adhesion properties thereof;
Forming a pattern of conductive material by depositing or plating the conductive material onto the exposed conductive substrate;
Laminating a film to the non-conducting substrate and pattern using an adhesive; and
Separating the film, conductive material and non-conductive substrate from the conductive substrate to form the master.

20. The method of claim 19, further characterised by the step of forming several masters from each conductive substrate.
